(19) United States
(12) Patent Application Publication
(10) Pub. No.: US 2026/0260859 A1
(43) Pub. Date: Sep. 3, 2026

(54) PLASMA DETECTION IN SEMICONDUCTOR FABRICATION APPARATUSES

(71) Applicant: Lam Research Corporation, Fremont, CA (US)

(72) Inventors: Yuhou Wang, Fremont, CA (US); Ananya Rajagopal, Campbell, CA (US); Michael John Martin, Fremont, CA (US); Luc Albarede, Fremont, CA (US); Alexander Miller Paterson, San Jose, CA (US)

(21) Appl. No.: 18/994,496

(22) PCT Filed: Jun. 29, 2023
(86) PCT No.: PCT/US2023/069386

§ 371 Date: Jan. 14, 2025

Related U.S. Application Data
(60) Provisional application No. 63/368,613, filed on Jul. 15, 2022.

(51) Int. Cl. H01J 37/32

(52) U.S. Cl. CPC H01J 37/3299; H01J 37/321; H01J 37/32183; H01J 2237/24564

(57) ABSTRACT

Methods and systems for detecting plasma are provided. In some embodiments, a method for detecting plasma comprises: obtaining data from one or more sensors, wherein the data characterizes a radio frequency (RF) power provided to one or more inductively-coupled plasma (ICP) coils of a semiconductor fabrication apparatus; determining a load impedance at an ICP coil of the one or more ICP coils using the data from the one or more sensors; and determining a presence or an absence of plasma at a location of the semiconductor fabrication apparatus within a vicinity of the ICP coil based on the load impedance at the ICP coil.

### INCORPORATION BY REFERENCE

A PCT Request Form is filed concurrently with this specification as part of the present application. Each application that the present application claim benefit of or priority to as identified in the concurrently filed PCT Request Form is incorporated by reference herein in its entirety and for all purposes.

### BACKGROUND

Detection of plasma within a process module or chamber of a semiconductor fabrication apparatus is important for accurate control of processes performed in the apparatus. However, it may be difficult to accurately detect plasma using non-invasive techniques that do not interface with wafer fabrication processes being conducted.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Methods, systems, and media for plasma detection in semiconductor fabrication apparatuses are provided.

According to some embodiments, a method of detecting plasma in semiconductor fabrication apparatuses is provided. The method may involve obtaining data from one or more sensors, wherein the data characterizes a radio frequency (RF) power provided to one or more inductively-coupled plasma (ICP) coils of a semiconductor fabrication apparatus. The method may involve determining a load impedance at an ICP coil of the one or more ICP coils using the data from the one or more sensors. The method may involve determining a presence or an absence of plasma at a location of the semiconductor fabrication apparatus within a vicinity of the ICP coil based on the load impedance at the ICP coil.

In some examples, the one or more sensors comprise at least one voltage-current sensor configured to measure a voltage at a first ICP coil of the one or more ICP coils, a current at the ICP coil of the one or more ICP coils, and a phase between the voltage and the current.

In some examples, the one or more sensors comprise at least one phase-magnitude sensor configured to measure a magnitude and a phase of an impedance at the ICP coil.

In some examples, determining the presence or the absence of the plasma comprises comparing the load impedance at the ICP coil to a predetermined threshold, and wherein plasma is determined to be present responsive to the load impedance exceeding the predetermined threshold.

In some examples, the obtained data comprises data obtained from a first set of sensors of the one or more sensors, and wherein the obtained data is utilized to determine a presence or an absence of plasma at a first location of the semiconductor fabrication apparatus within a vicinity of a first ICP coil of the one or more ICP coils; and the obtained data comprises data obtained from a second set of sensors of the one or more sensors, and wherein the obtained data is utilized to determine a presence or an absence of plasma at a second location of the semiconductor fabrication apparatus within a vicinity of a second ICP coil of the one or more ICP coils.

In some examples, the semiconductor fabrication apparatus comprises an impedance matching network. In some examples, the one or more sensors comprise a first sensor that measures characteristics of the RF power at an output of an RF generator operatively coupled to the impedance matching network and a second sensor that measures characteristics of the RF power at an input of the impedance matching network. In some examples, determining the load impedance comprises utilizing data from the first sensor, data from the second sensor, and a model of the impedance matching network. In some examples, the one or more sensors comprise a sensor at an output of the impedance matching network.

In some examples, the one or more sensors are utilized by a controller associated with the semiconductor fabrication apparatus to control a ratio of current provided to ICP coils of the one or more ICP coils.

According to some embodiments, one or more non-transitory computer-readable media including instructions that, when executed by one or more processors, cause the processors to perform a method of detecting plasma in semiconductor fabrication apparatuses is provided. The method may involve obtaining data from one or more sensors, wherein the data characterizes a radio frequency (RF) power provided to one or more inductively-coupled plasma (ICP) coils of a semiconductor fabrication apparatus. The method may involve determining a load impedance at an ICP coil of the one or more ICP coils using the data from the one or more sensors. The method may involve determining a presence or an absence of plasma at a location of the semiconductor fabrication apparatus within a vicinity of the ICP coil based on the load impedance at the ICP coil.

In some examples, the one or more sensors comprise at least one voltage-current sensor configured to measure a voltage at a first ICP coil of the one or more ICP coils, a current at the ICP coil of the one or more ICP coils, and a phase between the voltage and the current.

In some examples, the one or more sensors comprise at least one phase-magnitude sensor configured to measure a magnitude and a phase of an impedance at the ICP coil.

In some examples, determining the presence or the absence of the plasma comprises comparing the load impedance at the ICP coil to a predetermined threshold, and wherein plasma is determined to be present responsive to the load impedance exceeding the predetermined threshold.

In some examples, the obtained data comprises data obtained from a first set of sensors of the one or more sensors, and wherein the obtained data is utilized to determine a presence or an absence of plasma at a first location of the semiconductor fabrication apparatus within a vicinity of a first ICP coil of the one or more ICP coils; and the obtained data comprises data obtained from a second set of sensors of the one or more sensors, and wherein the obtained data is utilized to determine a presence or an absence of plasma at a second location of the semiconductor fabrication apparatus within a vicinity of a second ICP coil of the one or more ICP coils.

In some examples, the semiconductor fabrication apparatus comprises an impedance matching network. In some examples, the one or more sensors comprise a first sensor that measures characteristics of the RF power at an output of an RF generator operatively coupled to the impedance matching network and a second sensor that measures characteristics of the RF power at an input of the impedance matching network. In some examples, determining the load impedance comprises utilizing data from the first sensor, data from the second sensor, and a model of the impedance matching network. In some examples, the one or more sensors comprise a sensor at an output of the impedance matching network.

In some examples, the one or more sensors are utilized by a controller associated with the semiconductor fabrication apparatus to control a ratio of current provided to ICP coils of the one or more ICP coils.

### BRIEF DESCRIPTION OF THE DRAWINGS

FIG. 1 is a graph of optical emission spectroscopy (OES) intensity and plasma density as a function of power.

FIG. 2 is a graph of load resistance and plasma density as a function of power.

FIGS. 3A and 3B are schematic diagrams of inductively-coupled plasma apparatuses and sensors that may be used to determine load resistance at an ICP coil in accordance with some embodiments.

FIG. 4 is a flowchart of an example process for detecting plasma based on load resistance in accordance with some embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Plasma-based processes are frequently used in semiconductor fabrication, which may include etching processes and/or deposition processes. Plasma may be ignited using various different types of apparatuses, such as a capacitively coupled plasma (CCP) apparatus or an inductively coupled plasma (ICP) apparatus.

Detection of plasma is a critical function of a plasma processing tool. For example, detecting plasma may be critical to ensure process consistency and proper operation of the apparatus. While various plasma properties may be measured and/or characterized using in situ tools such as Langmuir probes, hairpin probes, energy analyzers, or the like, these tools may generally be used in research settings rather than during production, because use of such in situ tools may interfere with wafer processing. Accordingly, non-invasive plasma detection techniques may be preferred, to allow plasma to be detected while not interfering with wafer processing.

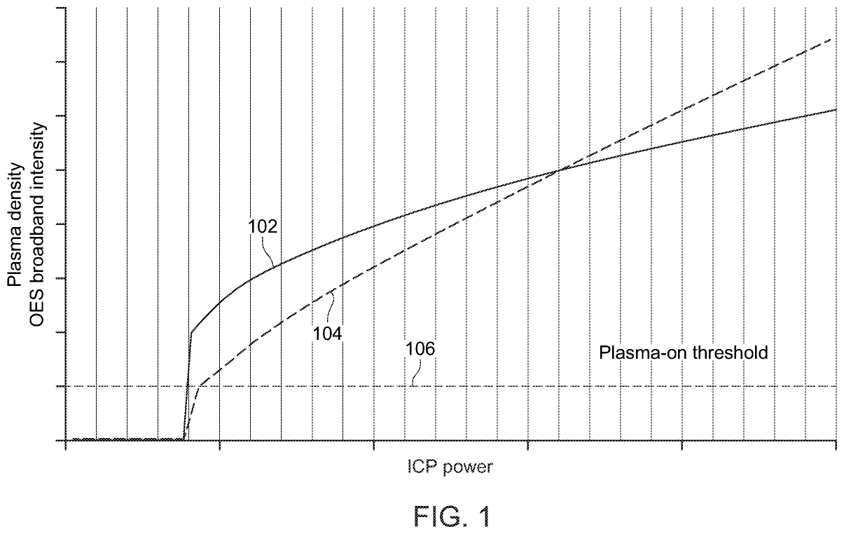

Optical emission spectroscopy (OES) is a conventional technique used for plasma detection. In OES, photon emissions from plasma may be detected. The detector may be a photodiode (e.g., that measures the intensity of the optical emissions from the plasma), or a spectrometer (e.g., that indicates relative intensity as a function of wavelength). When used for plasma detection, the intensity of the measured emissions is compared to a threshold, where plasma is considered to be present if the intensity exceeds the threshold. An example of this is shown in and described below in connection with FIG. 1.

However, OES may only be able to provide a generalized indication of whether plasma is present. In apparatuses that utilize multiple ICP coils, it may be advantageous to detect plasma at various regions of an apparatus, each region associated with an ICP coil. In addition, even though OES does not introduce any material into the plasma body, it is not fully non-invasive as it requires holes on the metallic chamber body to be filled with light transmitting materials.

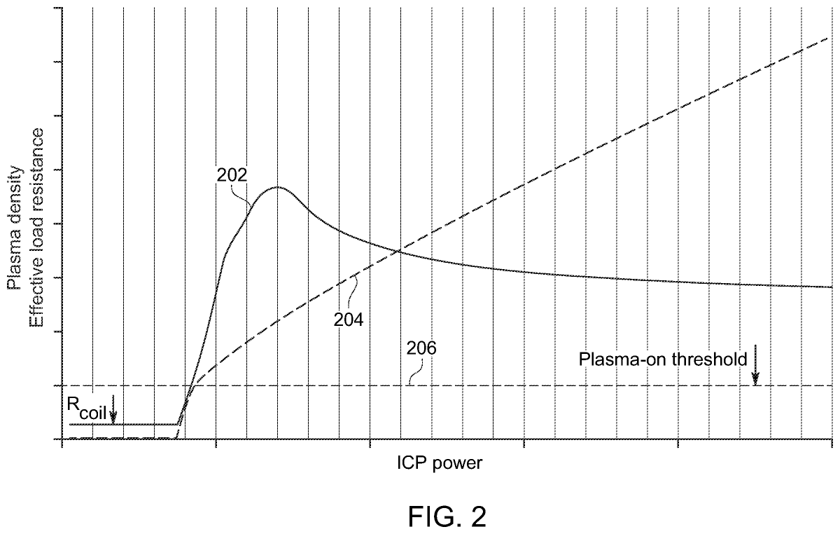

Disclosed herein are systems, methods, and techniques for detecting plasma in an ICP apparatus. As described below in more detail in connection with FIGS. 2, 3A, 3B, and 4, the techniques described herein determine an effective impedance at an ICP coil. Plasma is then detected based on the effective impedance at the ICP coil. For example, plasma may be considered present responsive to a determination that the effective impedance exceeds a threshold. As will be described below in more detail, the determination may be made for each ICP coil, thereby allowing localized detections of plasma to be made. It should be understood that the techniques described herein may be utilized with an apparatus that includes any suitable number of coils (e.g., one, two, five, ten, etc.). Additionally, the techniques described herein may be utilized with an apparatus that includes a matching network, or, alternatively, with a matchless plasma source. FIG. 2 illustrates a graph that depicts a relationship between measured load impedance and plasma intensity.

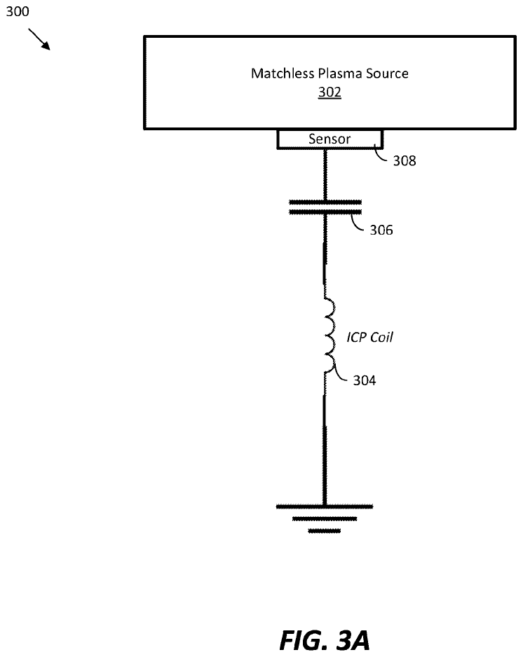

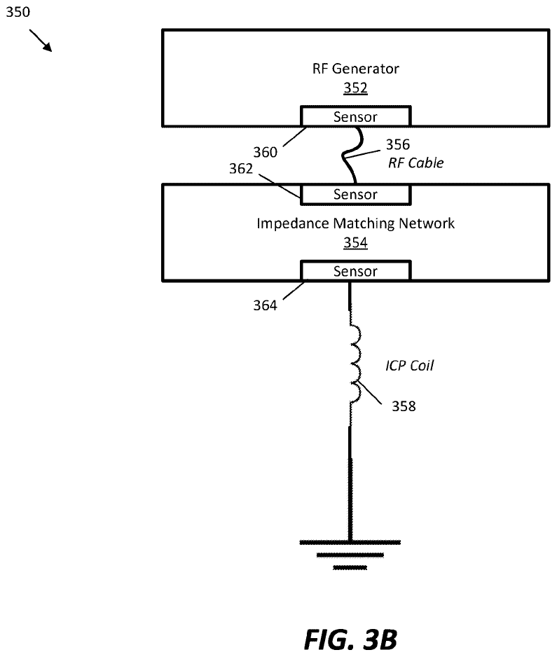

As described below in connection with FIGS. 3A and 3B, a load impedance at an ICP coil may be determined using various sensors that, e.g., measure voltage and/or current provided by a radio frequency (RF) generator or a phase and/or magnitude of impedance at the ICP coil. As described below in more detail in connection with FIG. 3B, in instances in which the apparatus includes an impedance matching network, the load resistance may be determined using a model of the impedance matching network. It should be noted that, in some embodiments, sensors utilized to determine load resistance at an ICP coil, and therefore, to detect plasma in the vicinity of the ICP coil, may be sensors that are included and utilized for other purposes in the apparatus (e.g., to control and/or monitor various processing steps). Accordingly, the techniques described herein may accurately and non-invasively detect plasma in a localized manner using existing sensors utilized for other purposes by the apparatus.

As described above, OES may be used to detect the presence of plasma within a process module or station. In particular, OES intensity may be compared to a threshold, where plasma is determined to be present responsive to the OES intensity exceeding a threshold. FIG. 1 is a graph that depicts the relationship between OES intensity and ICP power. As illustrated, both the OES broadband intensity (depicted by curve 102) and the plasma density (depicted by curve 104) increase as a function of ICP power. Note the step-wise change in both OES broadband intensity and plasma density corresponding to an ICP power at which plasma was ignited. Plasma may be detected by comparing the OES intensity to a plasma-on threshold 106, where plasma is considered to be present responsive to the OES intensity (e.g., curve 102) exceeding the plasma-on threshold 106.

As disclosed herein, effective impedance at an ICP coil may be used to detect the presence of plasma. FIG. 2 illustrates a graph that depicts the relationship between load impedance, plasma density, and ICP power. Curve 202 illustrates the effective load impedance at a given ICP coil as a function of ICP power. Curve 204 illustrates the plasma density as a function of ICP power. Note the step-wise increase in both load impedance and plasma density at a time when the ICP power is sufficient to ignite the plasma. In some implementations, plasma may be detected within a region proximate to the ICP coil responsive to the load impedance (e.g., curve 202) exceeding a plasma-on threshold 206. Note that, as illustrated by curve 202, the load impedance may decrease from a maximum while the plasma density increases due to a decrease in plasma resistance at high plasma densities. However, the load impedance still exceeds the plasma-on threshold 206, and accordingly, plasma may still be determined to be present.

In some implementations, a load impedance at an ICP coil may be determined using one or more sensors. The sensors may be existing sensors of an apparatus, e.g., that are utilized by a controller of the apparatus in performing and/or tuning processes performed by the apparatus. In some embodiments, the one or more sensors may include one or more voltage-current (VI) sensors (sometimes referred to as a “VI probe”) that measures a complex current and a complex voltage, and a phase difference between the complex current and the complex voltage. In some implementations, the load impedance may be determined based on the current and voltage measurements. In some embodiments, the one or more sensors may include one or more phase-magnitude sensors that measure a magnitude and a phase of impedance directly. The one or more sensors may be disposed and/or positioned to measure voltage, current, phase between current and voltage, impedance magnitude, and/or impedance phase at any suitable nodes of the system. For example, a sensor may be placed at an output of a matchless plasma source (e.g., as shown in and described below in connection with FIG. 3A), at the output of an RF generator (e.g., as shown in and described below in connection with FIG. 3B), and/or at an input and/or an output of an impedance matching network (e.g., as shown in and described below in connection with FIG. 3B).

FIG. 3A is a schematic diagram of an example apparatus 300 that utilizes a matchless plasma source in accordance with some embodiments. An apparatus with a matchless plasma source may be capable of striking a plasma in a plasma tool without use of an RF cable or an RF matching network or circuitry. As illustrated, apparatus 300 includes a matchless plasma source 302. Matchless plasma source 302 may serve to deliver RF power to an electrode, such as ICP coil 304. RF power from matchless plasma source 302 may be coupled to the electrode (e.g., ICP coil 304) via one or more power transistors (e.g., field-effect transistors (FETs), insulated-gate bipolar transistors (IGBTs), or the like). Matchless plasma source 302, by transferring RF power to ICP coil 304, may strike a plasma within a plasma chamber (not shown), which may be a chamber suitable for CVD processes, ALD processes, PECVD processes, PEALD processes, plasma-based etch processes, or the like. Capacitor 306 may serve to reduce the net reactance of the ICP coil load 304.

As illustrated, apparatus 300 includes a sensor 308, which is disposed at an output of matchless plasma source 302. In some implementations, sensor 308 may be a VI sensor that measures a voltage and/or current generated by matchless plasma source 302, and/or a phase difference between the current and the voltage. In some such implementations, an effective load impedance at ICP coil 304 may be determined based on the voltage and current measured by the VI sensor. In some implementations, sensor 308 may be a phase-magnitude sensor that directly measures a magnitude and phase of the impedance. In such implementations, the effective load impedance at ICP coil 304 may be directly determined based on an output of the phase-magnitude sensor.

It should be understood that, in instances in which an apparatus includes multiple ICP coils, there may be a sensor (e.g., a VI sensor and/or a phase-magnitude sensor) associated with each ICP coil. Accordingly, an effective load impedance may be determined in connection with each ICP coil using the outputs of the corresponding sensor. Accordingly, based on the load impedance for a given ICP coil, plasma may be detected in a region localized to the given ICP coil.

FIG. 3B illustrates an example apparatus 350 that utilizes an RF generator and an impedance matching network to transfer RF power to an ICP coil.

As illustrated, apparatus 350 includes an RF generator 352. RF generator 352 is operatively coupled to an impedance matching network 354 via an RF cable 356. Impedance matching network 354 may be configured to perform impedance matching across multiple stations of apparatus 350 and/or to reduce an amount of reflected power reflected back to RF generator 352, thereby increasing an amount of power delivered to ICP coil 358.

In order to determine a load impedance at ICP coil 358, one or more sensors of apparatus 350 may be used. In some implementations, a downstream sensor 364, positioned at an output of impedance matching network 354 may be used. Downstream sensor 364 may be a VI sensor that measures voltage, current, and/or a phase between the current and the voltage. Load impedance at ICP coil 358 may be determined based on a voltage and current measured by the VI sensor. Alternatively, in some embodiments, downstream sensor 364 may be a phase-magnitude sensor that measures a magnitude and/or phase of the impedance. The effective load impedance at ICP coil 358 may be determined directly from such a phase-magnitude sensor.

Additionally or alternatively, in some embodiments, the load impedance at ICP coil 358 may be determined based on one or more upstream sensors (e.g., upstream of ICP coil 358), such as RF generator sensor 360 and matching network input sensor 362. RF generator sensor 360 may be a VI sensor (e.g., that measures voltage, current, and/or phase difference at an output of RF generator 352) or a phase-magnitude sensor (e.g., that measures magnitude and phase of impedance at an output of RF generator 352). Matching network input sensor 362 may be a VI sensor (e.g., that measures voltage, current, and/or phase difference at an input of impedance matching network 354) or a phase-magnitude sensor (e.g., that measures magnitude and phase of impedance at an input of impedance matching network 354). In instances in which one or more upstream sensors are used, the outputs of the one or more upstream sensors may be used in conjunction with a model of impedance matching network 354 to determine the effective load impedance at ICP coil 358. The model of the impedance matching network may be, e.g., a lumped element circuit model. The model of the impedance matching network may characterize the impedance or load resistance at an output of the matching network such that the effective impedance at ICP coil 358 may be determined by subtracting the load resistance at the output of the matching network (e.g., as determined using the model of the impedance matching network) from the impedance measured using the one or more upstream sensors.

In instances in which multiple ICP coils are utilized, the apparatus may include a single RF generator and a single impedance matching network. In such instances, the effective load impedance at each ICP coil may be based on current ratios that represent a current split between multiple ICP coils. In some implementations, a sensor that measures current at each ICP coil may be used to determine the effective impedance at each coil, for example, using a model of the impedance matching network. It should be noted that sensors for measuring current at each ICP coil may already exist in the apparatus (e.g., to control current split ratios between the ICP coils), and therefore, determining effective load impedance at each coil may utilize outputs of existing sensors of the apparatus.

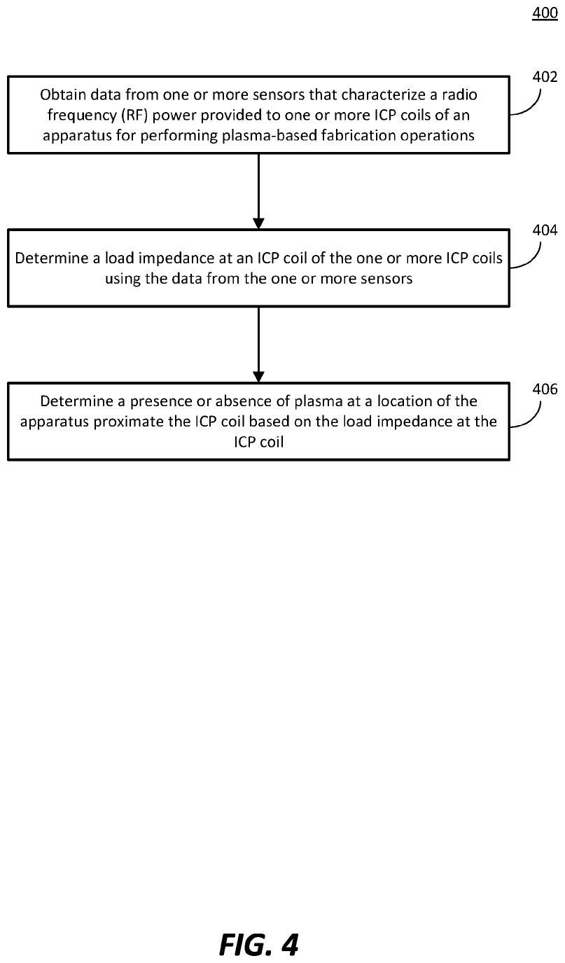

FIG. 4 is a flowchart of an example process 400 for detecting presence of plasma based on a determined load impedance at one or more ICP coils in accordance with some implementations. In some embodiments, blocks of process 400 may be performed by a controller or a processor associated with an apparatus. In some implementations, blocks of process 400 may be performed in an order other than what is shown in FIG. 4. In some embodiments, two or more blocks of process 400 may be performed substantially in parallel. In some embodiments, one or more blocks of process 400 may be omitted. It should be noted that process 400 may be performed in connection with an apparatus that includes a matchless plasma source (e.g., as shown in and described above in connection with FIG. 3A) or with an apparatus that includes an RF generator and an impedance matching network (e.g., as shown in and described above in connection with FIG. 3B).

At 402, process 400 can begin by obtaining data from one or more sensors that characterize an RF power provided to one or more ICP coils of an apparatus for performing plasma-based fabrication operations. The one or more sensors may include VI sensors and/or phase-magnitude sensors. In some implementations, in an instance in which the apparatus includes a matchless plasma source, the one or more sensors may be positioned at an output node of the matchless plasma source (e.g., as shown in and described above in connection with FIG. 3A). Alternatively, in an instance in which the apparatus includes an RF generator and an impedance matching network, the one or more sensors may include a downstream sensor at an output of the impedance matching network or two or more upstream sensors (e.g., at an output of the RF generator and an input of the impedance matching network), as shown in and described above in connection with FIG. 3B.

At 404, process 400 can determine a load impedance at an ICP coil of the one or more ICP coils using the data from the one or more sensors. In an instance in which the apparatus includes a matchless plasma source and the one or more sensors measure an output of the matchless plasma source, the load impedance may be determined based on the output of the one or more sensors. In an instance in which the apparatus includes an RF generator, an impedance matching network, and one or more downstream sensors at an output of the impedance matching network, the load impedance at an ICP coil may be determined based on the output of the one or more downstream sensors. In an instance in which the apparatus includes an RF generator, an impedance matching network, and two or more upstream sensors (e.g., at an output of the RF generator and at an input of the impedance matching network), the load impedance at an ICP coil may be determined based on the output of the two or more upstream sensors and a model of the impedance matching network, as described above in connection with FIG. 3B.

In instances in which the one or more sensors include phase-magnitude sensors, the load impedance at an ICP coil may be determined directly from the output of the phase-magnitude sensors. Additionally or alternatively, in instances in which the one or more sensors include VI sensors, the load impedance at an ICP coil may be determined based on the measured voltage and current measured by the VI sensors.

At 406, process 400 can determine a presence or an absence of plasma at a location of the apparatus proximate the ICP coil based on the load impedance at the ICP coil. The location may be a region within the plasma chamber proximate to the ICP coil. Process 400 may determine that plasma is present at the location responsive to determining that the effective load impedance exceeds a plasma-on threshold impedance. Conversely, process 400 may determine that plasma is absent at the location responsive to determining that the effective load impedance is less than the plasma-on threshold impedance. Note that the plasma-on threshold impedance may be determined in any suitable manner (e.g., during a calibration procedure) and stored for use during performance of process 400. Additionally, it should be noted that the determination at block 406 of presence or absence of plasma may be performed for each ICP coil of multiple ICP coils to determine the presence or absence of plasma at a location proximate each ICP coil. In some cases, plasma may be determined to be present in one region and absent in another region within the same plasma chamber.

### Controller

In some embodiments, the apparatuses described herein may include a controller that is configured to control various aspects of the apparatus in order to perform the techniques described herein. For example, the controller may be communicatively connected with and/or control some or all of the operations of a processing chamber. The system controller may include one or more memory devices and one or more processors. In some embodiments, the apparatus includes a switching system for controlling flow rates and durations, the substrate heating unit, the substrate cooling unit, the loading and unloading of a substrate in the chamber, the thermal floating of the substrate, and the process gas unit, for instance, when disclosed embodiments are performed. In some embodiments, the apparatus may have a switching time of up to about 300 ms, or up to about 750 ms. Switching time may depend on the flow chemistry, recipe chosen, reactor architecture, and other factors.

In some implementations, the controller is part of an apparatus or a system, which may be part of the above-described examples. Such systems or apparatuses can include semiconductor processing equipment, including a processing tool or tools, chamber or chambers, a platform or platforms for processing, and/or specific processing components (a gas flow system, a substrate heating unit, a substrate cooling unit, etc.). These systems may be integrated with electronics for controlling their operation before, during, and after processing of a semiconductor wafer or substrate. The electronics may be referred to as the “controller,” which may control various components or subparts of the system or systems. The controller, depending on the processing parameters and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing operations during the fabrication of one or more layers, materials, metals, oxides, silicon, silicon dioxide, surfaces, circuits, and/or dies of a wafer. The controller, or processors of the controller, may be configured to execute operations stored on non-transitory computer-readable media or computer-readable program instructions. The operations or program instructions may cause the controller, or one or more processors, to perform any of the techniques described above, such as detecting plasma based on a load impedance at an ICP coil.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing operations to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing operations to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

As noted above, depending on the process operation or operations to be performed by the apparatus, the controller might communicate with one or more of other apparatus circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

As also stated above, the controller is configured to perform any technique described above. This may include any of the above-described techniques for detecting plasma based on load impedance (e.g., as described above in connection with FIGS. 3A, 3B, and 4). This may include causing a substrate transfer robot to position the substrate in the chamber on the plurality of substrate supports causing power to be delivered to the LEDs so that they emit the visible light having wavelengths between 400 nm and 800 nm to heat the substrate to a first temperature, such as between 100° C. and 600° C., and causing etchant gases to flow into the chamber and etch the substrate. This may also include cooling, while the substrate is supported by only the plurality of substrate supports, the substrate by flowing the cooling gas onto the substrate, and/or moving the pedestal vertically so that the substrate is offset from a faceplate of a gas distribution unit by a first nonzero distance, and thereby causing heat to transfer from the substrate to the faceplate through noncontact radiation.

While the subject matter disclosed herein has been particularly described with respect to the illustrated embodiments, it will be appreciated that various alterations, modifications and adaptations may be made based on the present disclosure, and are intended to be within the scope of the present invention. It is to be understood that the description is not limited to the disclosed embodiments but, on the contrary, is intended to cover various modifications and equivalent arrangements included within the scope of the claims.

It is to be further understood that the above disclosure, while focusing on a particular example implementation or implementations, is not limited to only the discussed example, but may also apply to similar variants and mechanisms as well, and such similar variants and mechanisms are also considered to be within the scope of this disclosure. For the avoidance of any doubt, it is also to be understood that the above disclosure is at least directed to the following numbered implementations, as well as to other implementations that are evident from the above disclosure.

1. A method of detecting plasma in semiconductor fabrication apparatuses, the method comprising:
obtaining data from one or more sensors, wherein the data characterizes a radio frequency (RF) power provided to one or more inductively-coupled plasma (ICP) coils of a semiconductor fabrication apparatus;
determining a load impedance at an ICP coil of the one or more ICP coils using the data from the one or more sensors; and
determining a presence or an absence of plasma at a location of the semiconductor fabrication apparatus within a vicinity of the ICP coil based on the load impedance at the ICP coil.

2. The method of claim 1, wherein the one or more sensors comprise at least one voltage-current sensor configured to measure a voltage at a first ICP coil of the one or more ICP coils, a current at the ICP coil of the one or more ICP coils, and a phase between the voltage and the current.

3. The method of claim 1, wherein the one or more sensors comprise at least one phase-magnitude sensor configured to measure a magnitude and a phase of an impedance at the ICP coil.

4. The method of claim 1, wherein determining the presence or the absence of the plasma comprises comparing the load impedance at the ICP coil to a predetermined threshold, and wherein plasma is determined to be present responsive to the load impedance exceeding the predetermined threshold.

5. The method of claim 1, wherein:
the obtained data comprises data obtained from a first set of sensors of the one or more sensors, and wherein the obtained data is utilized to determine a presence or an absence of plasma at a first location of the semiconductor fabrication apparatus within a vicinity of a first ICP coil of the one or more ICP coils; and
the obtained data comprises data obtained from a second set of sensors of the one or more sensors, and wherein the obtained data is utilized to determine a presence or an absence of plasma at a second location of the semiconductor fabrication apparatus within a vicinity of a second ICP coil of the one or more ICP coils.

6. The method of claim 1, wherein the semiconductor fabrication apparatus comprises an impedance matching network.

7. The method of claim 6, wherein the one or more sensors comprise a first sensor that measures characteristics of the RF power at an output of an RF generator operatively coupled to the impedance matching network and a second sensor that measures characteristics of the RF power at an input of the impedance matching network.

8. The method of claim 7, wherein determining the load impedance comprises utilizing data from the first sensor, data from the second sensor, and a model of the impedance matching network.

9. The method of claim 6, wherein the one or more sensors comprise a sensor at an output of the impedance matching network.

10. The method of claim 1, wherein the one or more sensors are utilized by a controller associated with the semiconductor fabrication apparatus to control a ratio of current provided to ICP coils of the one or more ICP coils.

11. One or more non-transitory computer-readable media including instructions that, when executed by one or more processors, cause the one or more processors to perform a method of detecting plasma in semiconductor fabrication apparatuses, the method comprising:
obtaining data from one or more sensors, wherein the data characterizes a radio frequency (RF) power provided to one or more inductively-coupled plasma (ICP) coils of a semiconductor fabrication apparatus;
determining a load impedance at an ICP coil of the one or more ICP coils using the data from the one or more sensors; and
determining a presence or an absence of plasma at a location of the semiconductor fabrication apparatus within a vicinity of the ICP coil based on the load impedance at the ICP coil.

12. The one or more non-transitory computer-readable media of claim 11, wherein the one or more sensors comprise at least one voltage-current sensor configured to measure a voltage at a first ICP coil of the one or more ICP coils, a current at the ICP coil of the one or more ICP coils, and a phase between the voltage and the current.

13. The one or more non-transitory computer-readable media of claim 11, wherein the one or more sensors comprise at least one phase-magnitude sensor configured to measure a magnitude and a phase of an impedance at the ICP coil.

14. The one or more non-transitory computer-readable media of claim 11, wherein determining the presence or the absence of the plasma comprises comparing the load impedance at the ICP coil to a predetermined threshold, and wherein plasma is determined to be present responsive to the load impedance exceeding the predetermined threshold.

15. The one or more non-transitory computer-readable media of claim 11, wherein:
the obtained data comprises data obtained from a first set of sensors of the one or more sensors, and wherein the obtained data is utilized to determine a presence or an absence of plasma at a first location of the semiconductor fabrication apparatus within a vicinity of a first ICP coil of the one or more ICP coils; and
the obtained data comprises data obtained from a second set of sensors of the one or more sensors, and wherein the obtained data is utilized to determine a presence or an absence of plasma at a second location of the semiconductor fabrication apparatus within a vicinity of a second ICP coil of the one or more ICP coils.

16. The one or more non-transitory computer-readable media of claim 11, wherein the semiconductor fabrication apparatus comprises an impedance matching network.

17. The one or more non-transitory computer-readable media of claim 16, wherein the one or more sensors comprise a first sensor that measures characteristics of the RF power at an output of an RF generator operatively coupled to the impedance matching network and a second sensor that measures characteristics of the RF power at an input of the impedance matching network.

18. The one or more non-transitory computer-readable media of claim 17, wherein determining the load impedance comprises utilizing data from the first sensor, data from the second sensor, and a model of the impedance matching network.

19. The one or more non-transitory computer-readable media of claim 16, wherein the one or more sensors comprise a sensor at an output of the impedance matching network.

20. The one or more non-transitory computer-readable media of claim 11, wherein the one or more sensors are utilized by a controller associated with the semiconductor fabrication apparatus to control a ratio of current provided to ICP coils of the one or more ICP coils.
